(19) United States
(12) Patent Application Publication
(10) Pub. No.: US 2023/0095257 A1
(43) Pub. Date: Mar. 30, 2023

(54) DISPLAY PANEL AND PREPARATION METHOD THEREOF

(71) Applicant: Wuhan China Star Optoelectronics Semiconductor Display Technology Co., Ltd, Wuhan (CN)

(72) Inventor: Zesheng CHEN, Wuhan (CN)

(21) Appl. No.: 17/053,765

(22) PCT Filed: May 26, 2020
(86) PCT No.: PCT/CN2020/092252

§ 371 Date: Nov. 7, 2020

(30) Foreign Application Priority Data
Mar. 31, 2020 (CN) 202010244662.9

(51) Int. Cl. H10K 59/38; H10K 71/00; H10K 59/122; H10K 50/844; H10K 50/86

(52) U.S. Cl. CPC H01L 27/322; H01L 51/56; H01L 27/3246; H01L 51/5253; H01L 51/5284; H01L 2227/323

(57) ABSTRACT

A display panel and preparation method thereof are disclosed, the display panel including: a thin film transistor structure layer, an organic light-emitting diode (OLED) light-emitting layer including an anode, an encapsulation layer disposed on the OLED light-emitting layer, a color filter disposed on the encapsulation layer, wherein the color filter includes a plurality of color resist units and a black matrix around the color resist units, a planarization layer covering one side of the color filter away from the encapsulation layer, and an anti-reflection layer disposed on one side of the planarization layer away from the encapsulation layer.

### FIELD OF INVENTION

The present disclosure relates to a field of mobile-display panel, and more particularly to a display panel and a preparation method thereof.

### BACKGROUND

Although a polarizer (POL) may effectively reduce a reflectivity of panel under bright light, nearly 58% of light will be lost. For organic light-emitting diodes (OLEDs), the POL greatly increases a burden across a service life of the OLED; on the other hand, the POL is thick and brittle, which is not conducive to development of dynamic bending products. Accordingly, it is necessary to provide new materials, new technology and new process to replace the polarizer for developing dynamic bending products based on OLED display technology.

A color filter (CF), classified as POL-less technology, is currently applied to replace the POL. A thickness of a function layer of the OLED can be reduced from 100 microns to 5 microns, and a light outputting efficiency of the OLED can be increased from 42% to 60%. The CF includes red color resists (R), green color resists (G), blue color resists (B) and a black matrix (BM). Based on a self-luminous property of the OLEDs, a color resist should correspond to a red pixel unit, a green pixel unit, and a blue pixel unit of the OLEDs to form a color film function layer. A sprayed or ink-jet printed color film still has a high reflectivity of the OLED self-luminous light and environmental light.

A combination of the black matrix and an RGB color film may replace the function of circular polarizer of OLED device. Different from the method of circular polarizer to reduce the reflectivity by ¼ wave plate, a reflectivity of color film is reduced through the black matrix. In general, the black matrix and the RGB color film have a certain reflectance to external environment light, particularly the environment light penetrating the RGB color film is reflected by an anode of the OLED device, a strong reflection will occur at an opening area of the anode, the strong reflection is also a main source of POL-less technology. In addition, because of the strong reflection effect of the color film anode area, compared with the traditional polarizer, a whole reflection curve of the color film has higher transmittance in 380-780 nm band, resulting in an external surface of the OLED device not being dark enough and having a color shift.

Accordingly, it is necessary to provide a new type of display panel to overcome the flaw of the prior art.

### SUMMARY

An object of the present disclosure is to provide a display panel for resolving the problem in the prior art that the color film has higher transmittance rate at a particular wavelength, and an external surface of the OLED device has a color shift.

To achieve the above object, the present disclosure provides a display panel, the display panel includes: a thin film transistor structure layer; an OLED light-emitting layer including an anode; an encapsulation layer disposed on the OLED light-emitting layer; a color filter disposed on the encapsulation layer, the color filter includes a plurality of color resist units and a black matrix around the color resist units; a planarization layer covering one side of the color filter away from the encapsulation layer; and an anti-reflection layer disposed on one side of the planarization layer away from the encapsulation layer.

According to one embodiment of the present disclosure, the color resist units are red color resist units, green color resist units, or blue color resist units; and the color filter includes the red color resist units, the green color resist units, and the blue color resist units.

According to one embodiment of the present disclosure, the color resist units include a narrow-band transmittance rate color film layer, the red color resist units pass light of wavelengths ranging from 580 nm to 660 nm, the green color resist units pass light of wavelengths ranging from 500 nm to 580 nm, the blue color resist units pass light of wavelengths ranging from 440 nm to 500 nm. The narrow-band transmittance rate color film layer may greatly reduce the transmittance rate of light at a whole band, so as to realize surface optical properties of low reflectivity, and to improve the contrast ratio of the display panel. At the same time, the red color resist units, the green color resist units, and the blue color resist units have different light transmittance rates at different wavelengths, the narrow-band transmittance rate color film layer may reduce a half-peak width of an OLED luminescence spectra, and improves the color gamut of an image.

A maximum wavelength for a highest transmittance rate of the red color resist units is 615±15 nm, a maximum wavelength for a highest transmittance rate of the green color resist units is 530±15 nm, and a maximum wavelength for a highest transmittance rate of the blue color resist units is 470±15 nm.

According to one embodiment of the present disclosure, a thickness of the blue color resist unit is less than a thickness of the red color resist unit or a thickness of the green color resist unit. Because a light transmittance rate of the red color resist units in wavelength of 580 nm to 600 nm and a light transmittance rate of the green color resist units in wavelength of 500 nm to 580 nm are higher than a light transmittance rate of the blue color resist units in wavelength of 440 nm to 500 nm, so by setting the thickness of the blue color resist unit less than the thickness of the red color resist unit or the thickness of the green color resist unit, it may reduce the transmittance rate of the red color resist units and the green color resist units, so as to realize the transmittance rate balance of each color resist unit, thus to further reduce the reflectivity.

According to one embodiment of the present disclosure, a material of the anti-reflection layer includes an anti-reflection (AR) film, the AR film includes: a silica gel layer disposed on the planarization layer; a polyethylene terephthalate (PET) layer disposed on the silica gel layer; and an anti-glare (AG) layer disposed on the PET layer. The AR film may reduce light reflectivity from wavelengths of 380 nm to 780 nm, and improve the contrast ratio of image displayed on the display panel, thus improving the color gamut of an image and improving the problem of color shifting when a screen is turned off.

According to one embodiment of the present disclosure, a thickness of the anti-reflection layer ranges from 300 nm to 800 nm. As the thickness magnitude of the anti-reflection layer is the same as the magnitude of a wavelength, so the anti-reflection layer has no big influence on a thickness of the display panel.

According to one embodiment of the present disclosure, the thin film transistor structure layer includes: a substrate layer; an active layer disposed on the substrate layer; a gate insulating layer disposed on the active layer; a gate layer disposed on the gate insulating layer; a pixel definition layer disposed on the gate layer; and the OLED light-emitting layer disposed on the pixel definition layer.

According to one embodiment of the present disclosure, a material of the planarization layer includes an overcoat (OC) glue, a refractive index of the planarization layer is less than a refractive index of the color resist units. According to one embodiment of the present disclosure, the refractive index of the planarization layer is less than 1.5.

According to one embodiment of the present disclosure, the encapsulation layer includes: a first inorganic layer disposed on the OLED light-emitting layer; a first organic layer disposed on the first inorganic layer; and a second inorganic layer disposed on the first organic layer.

To achieve the above object, the present disclosure provides a preparation method for the display panel, including: providing the thin film transistor structure layer; preparing the OLED light-emitting layer disposed on the thin film transistor structure layer, the OLED light-emitting layer includes the anode; preparing the encapsulation layer disposed on the OLED light-emitting layer; preparing the color filter disposed on the encapsulation layer, including forming a plurality of color resist units and forming a black matrix around the color resist units; preparing the planarization layer covering one side of the color filter away from the encapsulation layer; preparing the anti-reflection layer disposed on one side of the planarization layer away from the encapsulation layer.

According to one embodiment of the present disclosure, a thickness of the black matrix ranges from 1.5 micron to 5 microns, the black matrix in the proportion of the color film is more than 50%.

According to one embodiment of the present disclosure, the color resist units are prepared by photoetching or ink-jet printing, the black matrix is prepared by coating.

According to one embodiment of the present disclosure, a material of the planarization layer includes silicon oxide.

The present disclosure provides a display panel and a preparation method thereof. On one hand, by setting an AR anti-reflection film layer, it is possible to reduce light reflectivity from wavelengths of 380 nm to 780 nm, and improve the contrast ratio of image displayed on the display panel, thus improving the color gamut of the image and improving the problem of color shifting when a screen is turned off. On the other hand, the color resist units include a narrow-band transmittance rate color film layer, the narrow-band transmittance rate color film layer may greatly reduce the transmittance rate of light at a whole band, so as to realize surface optical properties of low reflectivity, and to improve the contrast ratio of the display panel. At the same time, the red color resist units, the green color resist units, and the blue color resist units have different light transmittance rates at different wavelengths, the narrow-band transmittance rate color film layer may reduce a half-peak width of an OLED luminescence spectra, and improves the color gamut of an image.

### BRIEF DESCRIPTION OF DRAWINGS

The embodiments of the present disclosure will be described hereinafter with reference to the accompanying drawings, the technical solutions and the beneficial effects of the present disclosure will be obviously.

FIG. 1 is a schematic structural diagram of a display panel provided in the first embodiment of the present disclosure.

FIG. 2 is a schematic diagram of the transmittance to a narrow-band transmittance rate color film layer of a display panel provided in the first embodiment of the present disclosure.

FIG. 3 is a flow diagram of a method to manufacture a display panel provided in the first embodiment of the present disclosure.

FIG. 4 is a schematic structural diagram of a display panel provided in the second embodiment of the present disclosure.

FIG. 5 is a schematic diagram of a transmittance rate of red color resist units provided in the second embodiment of the present disclosure with the thickness of the layer at 1 micron, 2 microns, 3 microns, 4 microns.

FIG. 6 is a schematic diagram of a transmittance rate of green color resist units provided in the second embodiment of the present disclosure with the thickness of the layer at 1 micron, 2 microns, 3 microns, 4 microns.

FIG. 7 is a schematic diagram of a transmittance rate of blue color resist units provided in the second embodiment of the present disclosure with the thickness of the layer at 1 micron, 2 microns, 3 microns, 4 microns.

Reference Character Legend: display panel—100, thin film transistor structure layer—110, OLED light-emitting layer—120, encapsulation layer—130, color filter—140, planarization layer—150, anti-reflection layer—160, color resist units—141, black matrix—142, red color resist units—1411, green color resist units—1412, blue color resist units—1413, silica gel layer—161, PET layer—162, anti-glare (AG) layer—163, first inorganic layer—131, first organic layer—132, and second inorganic layer—133.

### DETAILED DESCRIPTION OF PREFERRED EMBODIMENTS

The technical solutions in the embodiments of the present disclosure will be described clearly and completely hereinafter with reference to the accompanying drawings in the embodiments of the present disclosure. Apparently, the described embodiments are merely some but not all embodiments of the present disclosure. All other embodiments obtained by persons with ordinary skill in the art based on the embodiments of the present disclosure without creative efforts shall fall within the protection scope of the present disclosure.

The following disclosure provides many different embodiments or examples for implementing different structures of the present disclosure. In order to simplify the descriptions of the present disclosure, the specific examples of the components and arrangements are described below. Of course, they are merely examples and are not intended to limit the present disclosure. In addition, the present disclosure may repeat reference numerals and/or letters in various examples, this repetition is for the purpose of simplification and clarity and does not by itself indicate the relationship between the various embodiments and/or arrangements discussed. In addition, the present disclosure provides various specific technologies and materials in examples, but persons with ordinary skill in the art may realize the use of other technologies and/or materials.

### First Embodiment

Please refer to FIG. 1, FIG. 1 is a schematic structural diagram of a display panel 100 provided in the present embodiment. The display panel 100 includes a thin film transistor structure layer 110, an OLED light-emitting layer 120, an encapsulation layer 130, a color filter 140, a planarization layer 150 and an anti-reflection layer 160.

In detail, the thin film transistor structure layer 110 includes: a substrate layer; an active layer disposed on the substrate layer; a gate insulating layer disposed on the active layer; a gate layer disposed on the gate insulating layer; and a pixel definition layer disposed on the gate layer. The improvement of the present embodiment is the anti-reflection layer 160, so the thin film transistor structure layer 110 will not be described in detail.

The OLED light-emitting layer 120 is disposed on the pixel definition layer, the OLED light-emitting layer 120 includes an anode.

The encapsulation layer 130 is disposed on the OLED light-emitting layer 120; the encapsulation layer 130 includes: a first inorganic layer 131 disposed on the OLED light-emitting layer 120; a first organic layer 132 disposed on the first inorganic layer 131; and a second inorganic layer 133 disposed on the first organic layer 132.

In one embodiment, a touch control layer is set between the encapsulation layer 130 and the color filter 140.

The color filter 140 is disposed on the encapsulation layer 130, the color filter 140 includes a plurality of color resist units 141 and a black matrix 142 around the color resist units 141. The color resist units 141 include red color resist units 1411, green color resist units 1412 and blue color resist units 1413. The color filter 140 includes the red color resist units 1411, the green color resist units 1412 and the blue color resist units 1413.

In the present embodiment, the color resist units 140 include a narrow-band transmittance rate color film layer. A light transmittance rate of the red color resist units 1411 for wavelengths ranging from 580 nm to 780 nm is more than 20%, a light transmittance rate of the green color resist units 1412 for wavelengths ranging from 500 nm to 580 nm is more than 20%, and a light transmittance rate of the blue color resist units 1413 for wavelengths ranging from 440 nm to 500 nm is more than 20%.

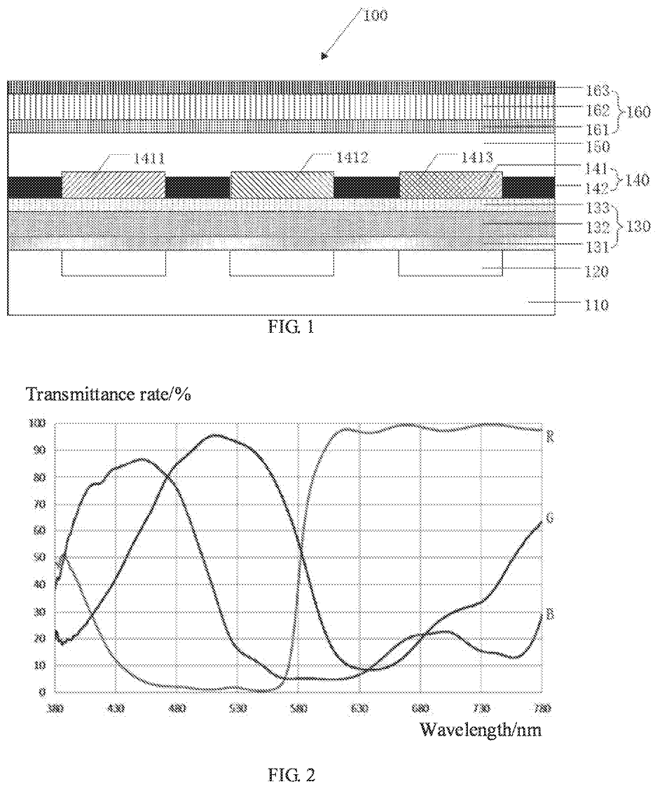

Please refer to FIG. 2, FIG. 2 is a schematic diagram of a transmittance rate of a narrow-band transmittance rate color film layer of a display panel provided in the present embodiment.

A maximum wavelength for a highest transmittance rate of the red color resist units 1411 is 615±15 nm, a maximum wavelength for a highest transmittance rate of the green color resist units 1412 is 530±15 nm, and a maximum wavelength for a highest transmittance rate of the blue color resist units 1413 is 470±15 nm.

The narrow-band transmittance rate color film layer may greatly reduce the transmittance rate of light at a whole band, so as to realize surface optical properties of low reflectivity, and to improve the contrast ratio of the display panel. At the same time, the red color resist units, the green color resist units, and the blue color resist units have different light transmittance rates at different wavelengths, the narrow-band transmittance rate color film layer may reduce a half-peak width of an OLED luminescence spectra, and improves the color gamut of an image.

A maximum wavelength for a highest transmittance rate of the red color resist units 1411 is 615±15 nm, a maximum wavelength for a highest transmittance rate of the green color resist units 1412 is 530±15 nm, and a maximum wavelength for a highest transmittance rate of the blue color resist units 1413 is 470±15 nm.

The planarization layer 150 covers on one side of the color filter 140 away from the encapsulation layer 130. A material of the planarization layer 150 includes an overcoat (OC) glue. A refractive index of the planarization layer 150 is less than a refractive index of the color resist units. In one embodiment, the refractive index of the planarization layer 150 is less than 1.5.

The anti-reflection layer 160 is disposed on one side of the planarization layer 150 away from the encapsulation layer 130. A material of the anti-reflection layer 160 includes an AR film, the AR film includes: a silica gel layer 161 disposed on the planarization layer 150; a PET layer 162 disposed on the silica gel layer 161; and an anti-glare (AG) layer 163 disposed on the PET layer 162.

The AR film may reduce light reflectivity from wavelengths of 380 nm to 780 nm, and improve the contrast ratio of image displayed on the display panel 100, thus improving the color gamut of the image and improving the problem of color shifting when a screen is turned off.

A thickness of the anti-reflection layer 160 ranges from 300 nm to 800 nm. As the thickness magnitude of the anti-reflection layer 160 is the same as the magnitude of a wavelength, so the anti-reflection layer has no big influence on the thickness of the display panel 100.

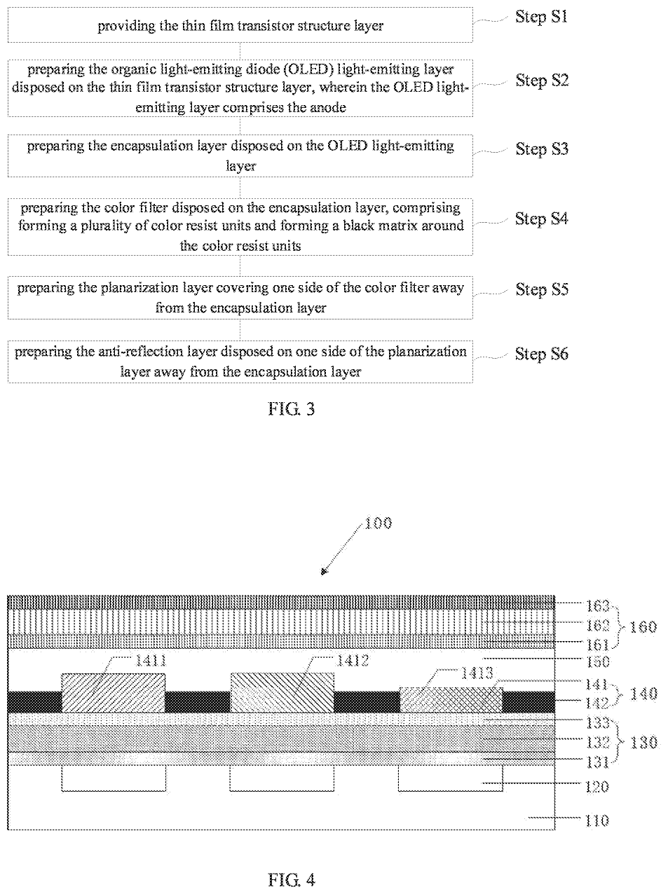

The present disclosure provides a preparation method for the display panel described in the present embodiment, the method includes the steps of S1 to S6. Please refer to FIG. 3, FIG. 3 is a flow diagram of a method to manufacture a display panel provided in the present embodiment.

Step S1: providing the thin film transistor structure layer 110.

Step S2: preparing the OLED light-emitting layer 120 disposed on the thin film transistor structure layer 110, the OLED light-emitting layer 120 includes the anode.

Step S3: preparing the encapsulation layer 130 disposed on the OLED light-emitting layer 120.

Step S4: preparing the color filter 140 disposed on the encapsulation layer 130, including forming a plurality of color resist units and forming a black matrix 142 around the color resist units.

The color resist units are prepared by photoetching or ink-jet printing, the black matrix 142 is prepared by coating. A thickness of the black matrix 142 ranges from 1.5 micron to 5 microns, the black matrix 142 in the proportion of the color film 140 is more than 50%.

Step S5: preparing the planarization layer 150 covering one side of the color filter 140 away from the encapsulation layer 130.

The material of the planarization layer 150 includes silicon oxide.

Step S6: preparing the anti-reflection layer 160 disposed on one side of the planarization layer 150 away from the encapsulation layer 130.

The present embodiment provides a display panel and a preparation method thereof. On one hand, by setting an AR anti-reflection film layer, it is possible to reduce light reflectivity from wavelengths of 380 nm to 780 nm, and improve the contrast ratio of image displayed on the display panel, thus improving the color gamut of the image and improving the problem of color shifting when a screen is turned off. On the other hand, the color resist units include a narrow-band transmittance rate color film layer, the narrow-band transmittance rate color film layer may greatly reduce the transmittance rate of light at a whole band, so as to realize surface optical properties of low reflectivity, and to improve the contrast ratio of the display panel. At the same time, the red color resist units, the green color resist units, and the blue color resist units have different light transmittance rates at different wavelengths, the narrow-band transmittance rate color film layer may reduce a half-peak width of an OLED luminescence spectra, and improves the color gamut of an image.

### Second Embodiment

The display panel provided in the present embodiment also includes a plurality of color resist units 141 and a black matrix 142 around the color resist units, which is the same roughly with the structure of the display panel provided in the first embodiment. The same structure of the display panel may refer to the descriptions in the first embodiment and will not be described here. The main difference between both is that a thickness of the blue color resist units 1413 is less than a thickness of the red color resist units 1411 or a thickness of the green color resist units 1412. Please refer to FIG. 4, FIG. 4 is a schematic structural diagram of a display panel 100 provided in the present embodiment.

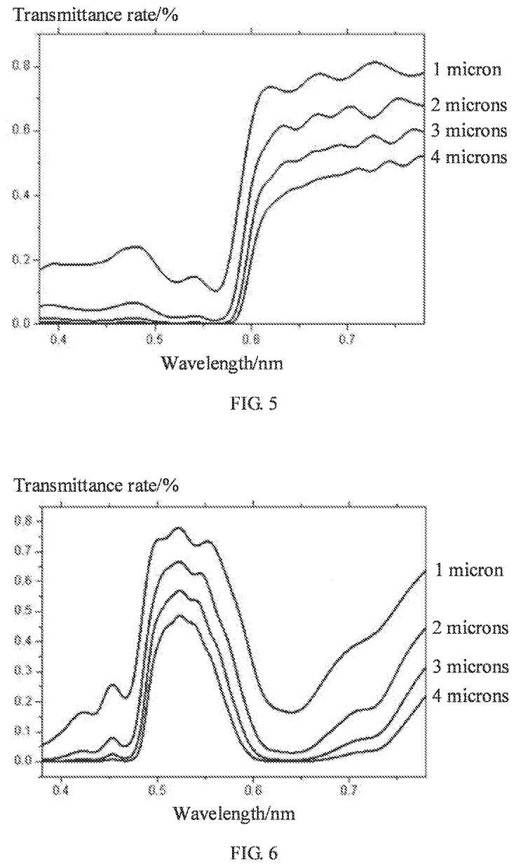

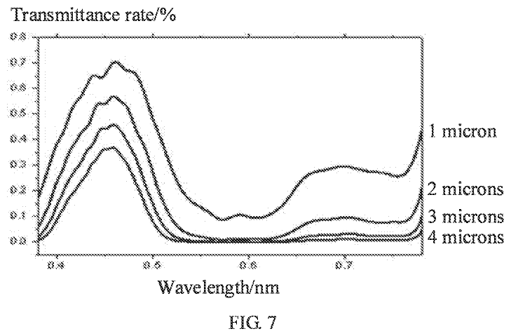

Please refer to FIG. 5, FIG. 6 and FIG. 7; FIG. 5 is a schematic diagram of the transmittance rate of the red color resist units provided in the present embodiment with thicknesses of 1 micron, 2 microns, 3 microns, 4 microns; FIG. 6 is a schematic diagram of the transmittance rate of the green color resist units provided in the present embodiment with thicknesses of 1 micron, 2 microns, 3 microns, 4 microns; FIG. 7 is a schematic diagram of the transmittance rate of the blue color resist units provided in the present embodiment with thicknesses of 1 micron, 2 microns, 3 microns, 4 microns.

As shown in the figures, a light transmittance rate of the red color resist units 1411 in wavelength of 580 nm to 600 nm and a light transmittance rate of the green color resist units 1412 in wavelength of 500 nm to 580 nm are higher than a light transmittance rate of the blue color resist units 1413 in wavelength of 440 nm to 500 nm.

So by setting the thickness of the red color resist units and the thickness of the green color resist units more than the thickness of the blue color resist units, it may reduce the transmittance rate of the red color resist units 1411 and the green color resist units 1412, so as to realize the transmittance rate balance of each color resist unit, thus to further reduce the reflectivity.

In the present embodiment, the thickness of the red color resist units 1411 is set as 2 microns, the thickness of the green color resist units 1412 is set as 2 microns, the thickness of the blue color resist units 1413 is set as 1 micron, so as to realize the transmittance rate balance of each color resist unit, thus to further reduce the reflectivity.

The present disclosure provides a display panel and a preparation method thereof. On one hand, the AR anti-reflection film layer may reduce light reflectivity from wavelengths of 380 nm to 780 nm, and improve the contrast ratio of image displayed on the display panel, thus improving the color gamut of the image and improving the problem of color shifting when a screen is turned off. On the other hand, the narrow-band transmittance rate color film layer includes color resist units, the narrow-band transmittance rate color film layer may greatly reduce the transmittance rate of light at a whole band, so as to realize surface optical properties of low reflectivity, and to improve the contrast ratio of the display panel. At the same time, the red color resist units, the green color resist units, and the blue color resist units have different light transmittance rate at different wavelengths, the narrow-band transmittance rate color film layer may reduce a half-peak width of an OLED luminescence spectra, and improves the color gamut of an image.

In the above descriptions, every embodiment has been illustrated. If there is any detail of certain embodiment not been mentioned, please refer to the relevant descriptions of other embodiments.

From the foregoing, the present disclosure is described in detail in accordance with the above contents with the specific examples, the present disclosure is not limited to the specific examples; for the person skilled in the art of the disclosure, various modifications or substitutions may be made without departing from the scope and spirit of the present disclosure, all of the modifications or substitutions should be included in the protection scope of the disclosure.

1. A display panel, comprising:
a thin film transistor structure layer;
an organic light-emitting diode (OLED) light-emitting layer comprising an anode;
an encapsulation layer disposed on the OLED light-emitting layer;
a color filter disposed on the encapsulation layer, the color filter comprises a plurality of color resist units and a black matrix around the color resist units;
a planarization layer covering on one side of the color filter away from the encapsulation layer; and
an anti-reflection layer disposed on one side of the planarization layer away from the encapsulation layer.

2. The display panel of claim 1, wherein the color resist units are red color resist units, green color resist units, or blue color resist units; and the color filter comprises the red color resist units, the green color resist units, and the blue color resist units.

3. The display panel of claim 2, wherein the color resist units comprise a narrow-band transmittance rate color film layer, the red color resist units pass light of wavelengths ranging from 580 nm to 660 nm, the green color resist units pass light of wavelengths ranging from 500 nm to 580 nm, and the blue color resist units pass light of wavelengths ranging from 440 nm to 500 nm.

4. The display panel of claim 2, wherein a thickness of the blue color resist unit is less than a thickness of the red color resist unit or a thickness of the green color resist unit.

5. The display panel of claim 1, wherein a material of the anti-reflection layer is an anti-reflection (AR) film, wherein the AR film comprises:
a silica gel layer disposed on the planarization layer;
a polyethylene terephthalate (PET) layer disposed on the silica gel layer; and
an anti-glare (AG) layer disposed on the PET layer.

6. The display panel of claim 1, wherein a thickness of the anti-reflection layer ranges from 300 nm to 800 nm.

7. The display panel of claim 1, wherein the thin film transistor structure layer comprises:
a substrate layer;
an active layer disposed on the substrate layer;
a gate insulating layer disposed on the active layer;
a gate layer disposed on the gate insulating layer;
a pixel definition layer disposed on the gate layer; and
the OLED light-emitting layer disposed on the pixel definition layer.

8. The display panel of claim 1, wherein a material of the planarization layer comprises an overcoat (OC) glue and a refractive index of the planarization layer is less than a refractive index of the color resist units.

9. The display panel of claim 1, wherein the encapsulation layer comprises:
a first inorganic layer disposed on the OLED light-emitting layer;
a first organic layer disposed on the first inorganic layer; and
a second inorganic layer disposed on the first organic layer.

10. A preparation method for the display panel of claim 1, comprising:
providing the thin film transistor structure layer;
preparing the organic light-emitting diode (OLED) light-emitting layer disposed on the thin film transistor structure layer, wherein the OLED light-emitting layer comprises the anode;
preparing the encapsulation layer disposed on the OLED light-emitting layer;
preparing the color filter disposed on the encapsulation layer, comprising forming a plurality of color resist units and forming a black matrix around the color resist units;
preparing the planarization layer covering one side of the color filter away from the encapsulation layer; and
preparing the anti-reflection layer disposed on one side of the planarization layer away from the encapsulation layer.

11. A display device, wherein the display device comprises the display panel of claim 1.

12. The display device of claim 11, wherein the color resist units are red color resist units, green color resist units, or blue color resist units; and the color filter comprises the red color resist units, the green color resist units, and the blue color resist units.

13. The display device of claim 12, wherein the color resist units comprise a narrow-band transmittance rate color film layer, the red color resist units pass light of wavelengths ranging from 580 nm to 660 nm, the green color resist units pass light of wavelengths ranging from 500 nm to 580 nm, and the blue color resist units pass light of wavelengths ranging from 440 nm to 500 nm.

14. The display device of claim 12, wherein a thickness of the blue color resist unit is less than a thickness of the red color resist unit or a thickness of the green color resist unit.

15. The display device of claim 11, wherein a material of the anti-reflection layer is an anti-reflection (AR) film, wherein the AR film comprises:
a silica gel layer disposed on the planarization layer;
a polyethylene terephthalate (PET) layer disposed on the silica gel layer; and
an anti-glare (AG) layer disposed on the PET layer.

16. The display device of claim 11, wherein a thickness of the anti-reflection layer ranges from 300 nm to 800 nm.

17. The display device of claim 11, wherein the thin film transistor structure layer comprises:
a substrate layer;
an active layer disposed on the substrate layer;
a gate insulating layer disposed on the active layer;
a gate layer disposed on the gate insulating layer;
a pixel definition layer disposed on the gate layer; and
the OLED light-emitting layer disposed on the pixel definition layer.

18. The display device of claim 11, wherein a material of the planarization layer comprises an overcoat (OC) glue and a refractive index of the planarization layer is less than a refractive index of the color resist units.

19. The display device of claim 11, wherein the encapsulation layer comprises:
a first inorganic layer disposed on the OLED light-emitting layer;
a first organic layer disposed on the first inorganic layer; and
a second inorganic layer disposed on the first organic layer.
